(19) United States
(12) Patent Application Publication
(10) Pub. No.: US 2018/0337228 A1
(43) Pub. Date: Nov. 22, 2018

(54) NOVEL SEAL RING FOR III-V COMPOUND SEMICONDUCTOR-BASED DEVICES

(71) Applicant: Taiwan Semiconductor Manufacturing Co., Ltd., Hsin-Chu (TW)

(72) Inventors: Ming-Hong CHANG, Hsin-Chu (TW); Po-Tao Chu, New Taipei City (TW); Shen-Ping Wang, Keelung City (TW); Chien-Li Kuo, Hsinchu City (TW); Chung-Cheng Chen, Hsin-Chu (TW)

(21) Appl. No.: 15/598,644

(22) Filed: May 18, 2017

(51) Int. Cl. H01L 29/06; H01L 29/20; H01L 23/48; H01L 21/768

(52) U.S. Cl. CPC H01L 29/0607; H01L 21/76898; H01L 23/481; H01L 29/2003

(57) ABSTRACT

A semiconductor device includes a substrate, overlaid by a III-V compound semiconductor layer. The substrate includes a circuit region and a seal ring region, wherein the seal ring region surrounds the circuit region. A seal ring structure is disposed in the seal ring region, wherein the seal ring structure includes a first via structure, extending through part of the substrate and the III-V compound semiconductor layer, that surrounds the circuit region.

### BACKGROUND

Group-III/V compound semiconductors (often referred to as III-V compound semiconductors) have been under intense research in recent years due to their promising applications in electronic and optoelectronic devices. Large band gaps and high electron saturation velocities of such III-V compound semiconductors make them excellent candidates to be used in high temperature, high-speed, and/or high power electronic/optoelectronic applications. Various examples of electronic devices employing such III-V compound semiconductors include high electron mobility transistors (HEMT's) and other heterojunction bipolar transistors. Various examples of optoelectronic devices employing such III-V compound semiconductors include blue light emitting diodes (LED's), laser diodes, and ultra-violet (UV) photo-detectors.

In general, such devices are formed on one or more epitaxially grown III-V compound semiconductor (e.g., gallium nitride (GaN)) films that are grown on a wafer-scale group IV semiconductor substrate (e.g., a silicon wafer) because of silicon's lower cost as compared to other growth substrates and processing compatibilities. After the devices are formed in a respective die on the wafer that typically includes millions of dies, for example, at least one die preparation process (e.g., a sawing process, a laser cutting process, etc.) is performed to “singulate” each of the dies from one another to form respective semiconductor chips. As such, each semiconductor chip can be packaged individually. However, the singulation process can cause various types of mechanical damage (e.g., crack, delamination, etc.) to the one or more epitaxially grown III-V compound semiconductor films of each die, which in turn deteriorates yield and/or performance of the already formed devices on the die.

### BRIEF DESCRIPTION OF THE DRAWINGS

Aspects of the present disclosure are best understood from the following detailed description when read with the accompanying figures. It is noted that various features are not necessarily drawn to scale. In fact, the dimensions and geometries of the various features may be arbitrarily increased or reduced for clarity of discussion.

FIG. 1 illustrates a flow chart of an embodiment of a method to form a semiconductor device, in accordance with some embodiments.

FIGS. 2, 3, 4B, 5, 6, 7, 8, and 9B illustrate cross-sectional views of an exemplary semiconductor device, made by the method of FIG. 1, during various fabrication stages, in accordance with some embodiments.

FIGS. 4A and 9A illustrate corresponding top views of FIGS. 4B and 9B, respectively, in accordance with some embodiments.

### DETAILED DESCRIPTION OF EXEMPLARY EMBODIMENTS

The following disclosure describes various exemplary embodiments for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides various embodiments of a semiconductor device including a seal ring structure that is used to protect the semiconductor device, more specifically, active circuit components (e.g., transistors) of the semiconductor device surrounded by the seal ring structure, from the above-mentioned mechanical damage during the one or more die preparation processes. In some embodiments, such a seal ring structure may be used to further protect the semiconductor device from moisture degradation, ionic contamination during the die preparation processes and/or some subsequent packaging processes. In some embodiments, such a semiconductor device may be formed on at least one III-V compound semiconductor (e.g., GaN) layer disposed (e.g., epitaxially grown) on a respective silicon chip (typically known as a “silicon die”) that is singulated from a silicon wafer through die preparation processes. Accordingly, the active circuit components of the semiconductor device may include various GaN-based devices such as, for example, GaN-based high-voltage transistors, GaN-based light emitting diodes (LED's), GaN-based high-electron mobility transistors (HEMT's), or the like.

In some embodiments, the disclosed seal ring structure includes a wall structure that closely surrounds the active circuit components of the semiconductor device, and a through-GaN-via (TGV) structure that further surrounds the wall structure. In some embodiments, the wall structure and the TGV structure of each semiconductor device are formed in a seal ring region after the semiconductor device's respective active circuit components are formed in a circuit region, but before the above-mentioned die preparation processes. In other words, plural such semiconductor devices, including respective active circuit components and seal ring structures, may be formed on a wafer (e.g., a silicon wafer) in respective areas, and the one or more die preparation processes are subsequently performed to singulate each of the semiconductor devices. As such, the disclosed seal ring structure that includes the wall structure and the TGV structure may advantageously provide at least two layers of protection against any mechanical damage that may be incurred during the one or more die preparation processes.

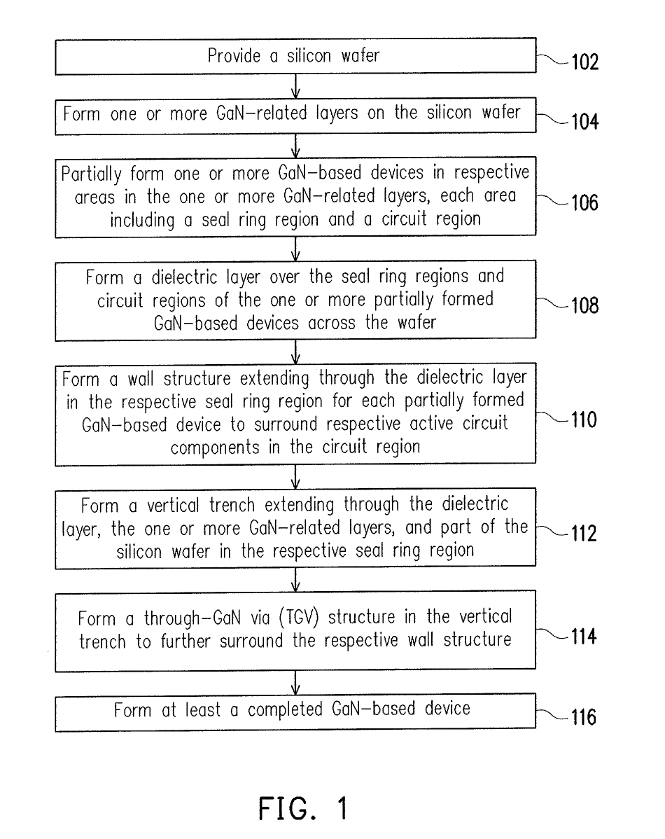

FIG. 1 illustrates a flowchart of a method 100 to form a semiconductor device according to one or more embodiments of the present disclosure. It is noted that the method 100 is merely an example, and is not intended to limit the present disclosure. In some embodiments, the semiconductor device is, at least part of, a GaN-based device. The term “GaN-based device” used herein refers to a semiconductor device that includes at least one component formed of GaN (or the like) material. As employed in the present disclosure, the GaN-based device refers to any GaN-based semiconductor devices such as, for example, GaN-based transistors, GaN-based diodes, etc. However, it is noted that the method 100 is not limited to making such a GaN-based device. That is, the method 100 can be used to make any of a variety of IV semiconductor (e.g., silicon (Si)) and III-V compound semiconductor (e.g., gallium arsenide (GaAs), gallium phosphide (GaP), indium phosphide (InP), indium arsenide (InAs), indium gallium arsenide (InGaAs), or a combination thereof)-based devices while remaining within the scope of the present disclosure. It is also noted that the method of FIG. 1 does not produce a completed GaN-based device. A completed GaN-based device may be fabricated using complementary metal-oxide-semiconductor (CMOS) technology processing. Accordingly, it is understood that additional operations may be provided before, during, and after the method 100 of FIG. 1, and that some other operations may only be briefly described herein.

In some embodiments, the method 100 starts with operation 102 in which a silicon wafer is provided. The method 100 continues to operation 104 in which one or more GaN-related layers is formed on the silicon wafer. The method 100 continues to operation 106 in which one or more GaN-based devices are partially formed in respective areas in the one or more GaN-related layers, wherein each area includes a respective circuit region and a respective seal ring region that surrounds the circuit region. In some embodiments, at operation 106, each partially formed GaN-based device includes one or more active circuit components formed in the respective circuit region. The method 100 continues to operation 108 in which a dielectric layer is formed over the seal ring regions and circuit regions of the one or more partially formed GaN-based devices across the silicon wafer. The method 100 continues to operation 110 in which a wall structure extending through the dielectric layer in the seal ring region is formed for each partially formed GaN-based device so as to surround the respective active circuit components in the circuit region. The method 100 continues to operation 112 in which a vertical trench extending through part of the silicon wafer, the one or more GaN-related layers, and the dielectric layer in the seal ring region is formed for each partially formed GaN-based device. The method 100 continues to operation 114 in which a through-GaN-via (TGV) structure in the respective vertical trench of each partially formed GaN-based device is formed so as to further surround the respective wall structure. The method 100 continues to operation 116 in which at least a completed GaN-based device (or a GaN-based die) is formed by singulating a respective partially formed GaN-based device.

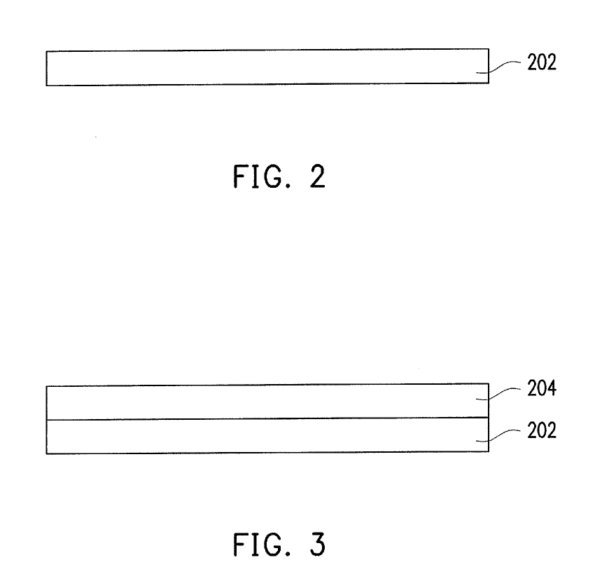

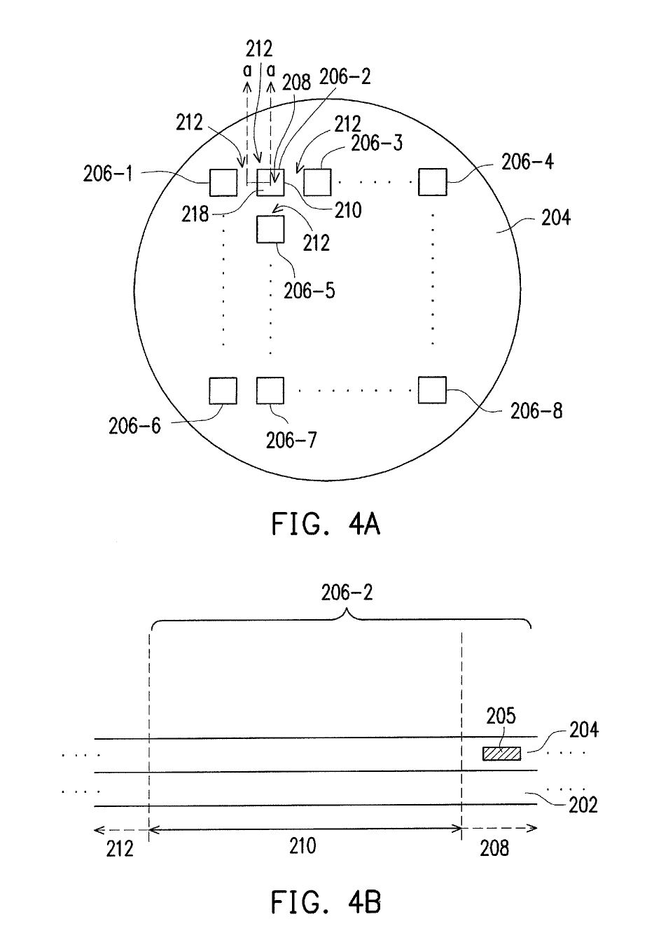

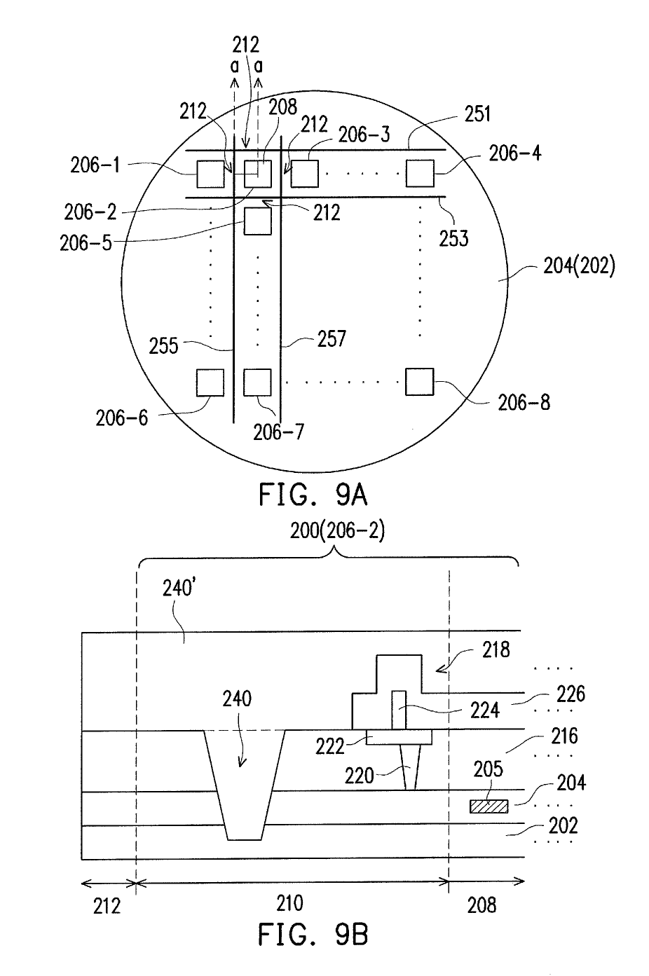

In some embodiments, operations of the method 100 may be associated with cross-sectional views of a semiconductor device 200 at various fabrication stages as shown in FIGS. 2, 3, 4B, 5, 6, 7, 8, and 9B, respectively. Further, for purposes of illustration, FIGS. 4A and 9A are provided to illustrate top views of the semiconductor device 200, together with plural similar semiconductor devices, formed on a common wafer, which will be discussed in further detail below. In some embodiments, the semiconductor device 200 may be a GaN-based device. The GaN-based device 200 may be included in a microprocessor, memory cell, and/or other integrated circuit (IC). Also, FIGS. 2 through 8B are simplified for a better understanding of the concepts of the present disclosure. For example, although the figures illustrate the GaN-based device 200, it is understood the IC may comprise any desired number of other devices, for example, resistors, capacitors, inductors, fuses, etc., which are not shown in FIGS. 2 through 8B, for purposes of clarity of illustration.

Corresponding to operation 102 of FIG. 1, FIG. 2 illustrates a cross-sectional view of a wafer 202 that is used to formed the GaN-based device 200 at one of the various stages of fabrication, according to some embodiments. In some embodiments, the wafer 202 comprises a crystalline silicon material (e.g., a silicon wafer). In some alternative embodiments, the wafer 202 may be made from some other suitable elemental semiconductor, such as diamond or germanium. Further, the wafer 202 may include a silicon-on-insulator (SOI) structure.

Corresponding to operation 104 of FIG. 1, FIG. 3 illustrates a cross-sectional view of a GaN-related layer 204 that is formed on the wafer 202 at one of the various stages of fabrication, according to some embodiments. Although, in the illustrated embodiment of FIG. 3, the GaN-related layer 204 is shown as a single layer, it is noted that such a GaN-related layer 204 may include multiple GaN-related layers that are used to form a GaN-based device, in accordance with some embodiments. Depending on applications for which the GaN-based device 200 is used, a variety of III-V compound semiconductors may be used to form such a GaN-related layer 204, which will be discussed in further detail below.

In an example where the GaN-based device 200 is configured to function as a HEMT (high-electron mobility transistor), the GaN-related layer 204 may include a nucleation layer, a graded layer, a bulk layer, and/or a donor-supply layer stacked on top of one another, which are not shown for purposes of brevity. In some embodiments, the nucleation (e.g., aluminum nitride (AlN)) layer may be first formed on the silicon wafer 202, the graded layer (e.g., aluminum gallium nitride (AlGaN)) that has a concentration gradient with reducing Al content and increasing Ga content, for example, in a direction moving away from the silicon wafer 202, may be subsequently formed on the AlN nucleation layer, and the bulk layer (e.g., gallium nitride (GaN)) may be formed on the AlGaN graded layer with the donor-supply layer (e.g., AlGaN) formed on the GaN bulk layer. It is noted that such a composition of the GaN-related layer 204, described above, is merely an example provided for purposes of explanation. Thus, it is understood by people of ordinary skill in the art that the GaN-related layer 204 may include at least one GaN layer (e.g., the GaN bulk layer) with various other III-V compound semiconductor (e.g., AlGaN, InAs, GaAs, InGaAs, InP, GaP, etc.), and/or one or more IV semiconductor (e.g., Si, Ge, C, etc.) layers that are stacked on top of one another while remaining within the scope of the present disclosure.

In some embodiments, each of the above-mentioned “sub” layers of the GaN-related layer 204 (e.g., the AlN nucleation layer, the AlGaN graded layer, the GaN bulk layer, the AlGaN donor-supply layer, etc.) may be formed by at least one of the following processes: a metal organic chemical vapor deposition (MOCVD) process, a metal organic vapor phase epitaxy (MOVPE) process, a plasma enhanced chemical vapor deposition (PECVD) process, a remote plasma enhanced chemical vapor deposition (RPCVD) process, a molecular beam epitaxy (MBE) process, a hydride vapor phase epitaxy (HYPE) process, a chloride vapor-phase epitaxy (Cl-VPE) process, and a liquid phase epitaxy (LPD) process.

Corresponding to operation 106 of FIG. 1, FIG. 4A illustrates a top view of the GaN-related layer 204 in which plural partially formed GaN-based devices (e.g., 206-1, 206-2, 206-3, 206-4, 206-5, 206-6, 206-7, 206-8, etc.) are disposed across the GaN-related layer 204 in respective areas at one of the various stages of fabrication, according to some embodiments, and FIG. 4B is a cross-sectional view, taken along line a-a of FIG. 4A, illustrating part of the partially formed GaN-based device 206-2 and part of respective scribe line region. Although only 8 partially formed GaN-based devices are shown in the illustrated embodiment of FIG. 4A, it is noted that any desired number (e.g., millions or more) of such partially formed GaN-based devices can be formed across the GaN-related layer 204 (also the non-shown silicon wafer 202) while remaining within the scope of the present disclosure. In some embodiments, each of the partially formed GaN-based devices (e.g., 206-1, 206-2, 206-3, 206-4, 206-5, 206-6, 206-7, 206-8, etc.) may be further formed to provide a completed GaN-based device 200, as discussed in further detail below with respect to FIG. 9B.

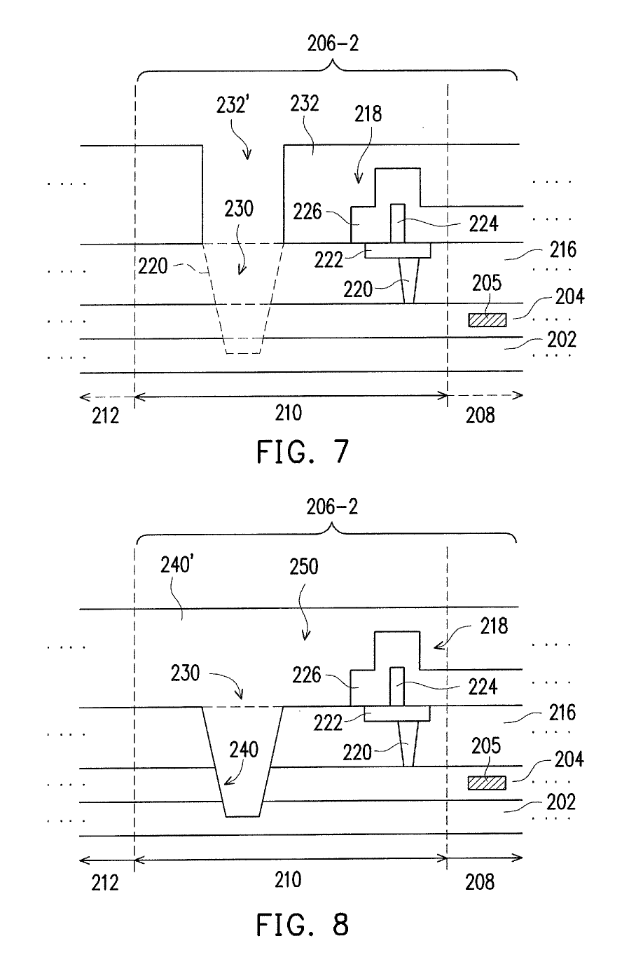

As shown in FIG. 4A, the partially formed GaN-based devices (e.g., 206-1, 206-2, 206-3, 206-4, 206-5, 206-6, 206-7, 206-8, etc.), across the GaN-related layer 204, are each disposed within a respective area 208. In some embodiments, such an area 208 is herein referred to as a “circuit region” of each partially formed GaN-based device (e.g., 206-1, 206-2, 206-3, 206-4, 206-5, 206-6, 206-7, 206-8, etc.). In some embodiments, the circuit region 208 may be the region where respective active circuit components of each partially formed GaN-based device (e.g., 206-1, 206-2, 206-3, 206-4, 206-5, 206-6, 206-7, 206-8, etc.) can be formed. In some embodiments, each circuit region 208 may be surrounded by a respective seal ring region 210 where a seal ring structure can be formed, as discussed in further detail below with respect to FIGS. 7 and 8. Moreover, once the respective active circuit components are formed within each respective circuit region surrounded by the respective seal ring region, a “scribe line region” where one or more die preparation processes can be performed may be accordingly formed around the seal ring region, as described in further detail below.

In some embodiments, since the partially formed GaN-based devices (e.g., 206-1, 206-2, 206-3, 206-4, 206-5, 206-6, 206-7, 206-8, etc.) are substantially similar to one another, the partially formed GaN-based device 206-2 is selected as a representative example in the following discussion. Moreover, the partially formed GaN-based device 206-2 is representatively selected to be subsequently formed as the completed GaN-based device 200, as discussed in further detail below with respect to FIG. 9B.

Accordingly, in such a representative example, the partially formed GaN-based device 206-2 may have its respective active circuit components, which will be discussed below, formed within respective circuit region 208. Further, the circuit region 208 is surrounded by seal ring region 210, and at least a side of the seal ring region 210 is abutted by scribe line region 212, as shown in FIG. 4A. In the illustrated embodiment of FIG. 4A, four sides of seal ring region 210 are all abutted (e.g., surrounded) by the scribe line region 212. According to some embodiments, such a scribe line region may be used by each partially formed GaN-based device to space itself from neighboring partially formed GaN-based device(s).

In FIG. 4A, the partially formed GaN-based device 206-2 may use the scribe line region 212 (at the left, right, and bottom) to space itself from the partially formed GaN-based device 206-1, the partially formed GaN-based device 206-2, and the partially formed GaN-based device 206-5, respectively. As such, one or more die preparation processes (e.g., die sawing processes) can follow the scribe line region to cut out the partially formed GaN-based device 206-2 from other partially formed GaN-based devices, which will be discussed in further detail below with respect to FIG. 9.

Referring now to FIG. 4B, the cross-sectional view of part of the partially formed GaN-based device 206-2 and the left part of the scribe line region 212 that is disposed between the partially formed GaN-based device 206-1 and the partially formed GaN-based device 206-2 is shown. Thus, it is understood that the illustrated embodiment of FIG. 4B (and the cross-sectional views of the following figures) only includes a portion of the partially formed GaN-based device 206-2 and a portion of the scribe line region 212.

As mentioned above, the active circuit components of each partially formed GaN-based device are formed in the respective circuit region. As shown in FIG. 4B, the partially formed GaN-based device 206-2's active circuit components 205 are formed in circuit region 208. It is noted that, in general, each partially formed GaN-based device (e.g., 206-2) may comprise plural active circuit components that are respectively formed to collectively provide one or more desired function. Thus, although the active circuit components 205 of the partially formed GaN-based device 206-2 are shown as a single component in FIG. 4B, it is understood that it is merely for purposes of illustration. The partially formed GaN-based device 206-2 may include plural active circuit components (e.g., 205) while reaming within the scope of the present disclosure. In accordance with some embodiments of the present disclosure, such active circuit components (e.g., 205) of each partially formed GaN-based device (e.g., 206-2) may include, but not limited to, a GaN-based superlattice structure, a GaN-based single quantum well structure, a GaN-based multiple quantum well structure, a GaN-based quantum dot structure, a GaN-based quantum wire structure, an n-type and/or a p-type doped GaN-based structure, etc.

Continuing with the above example where the partially formed GaN-based device 206-2 is configured to function as the HEMT (high-electron mobility transistor), the active circuit components 205 may include part of the above-mentioned AlN nucleation layer, the AlGaN graded layer (as a quantum well structure, for example), the GaN bulk layer, and the AlGaN donor-supply layer of the GaN-related layer 204. Moreover, in some embodiments, during operation 106 of the method 100 (FIG. 1), some of the active circuit components 205 may be respectively formed in a particular structure/shape so as to collectively provide a desired function of the HEMT.

For example, after the AlN nucleation layer, the AlGaN graded layer, the GaN bulk layer, and the AlGaN donor-supply layer are formed on the silicon wafer 202 (operation 104), part of the AlGaN donor-supply layer and the GaN bulk layer in the circuit region 208 of the partially formed GaN-based device 206-2 are recessed to allow at least a contact to be formed in the recessed portion such that two-dimensional electron gas (2DEG) can be induced in the GaN bulk layer when applying a voltage signal to the bulk GaN layer through the contact. It is understood by people of ordinary skill in the art that such 2DEG may serve as a conduction carrier channel in the HEMT. In other words, when the 2DEG is induced, the desired function of the HEMT may be accordingly reached.

The above example of the HEMT is merely an example provided to illustrate that the circuit region 208 of the partially formed GaN-based device 206-2 includes one or more active circuit components (e.g., 205) that are formed based on the GaN-related layer 204. It is noted that a variety of other active circuit components formed based on the GaN-related layer 204 can be formed in the circuit region 208 of the partially formed GaN-based device 206-2 while remaining within the scope of the present disclosure.

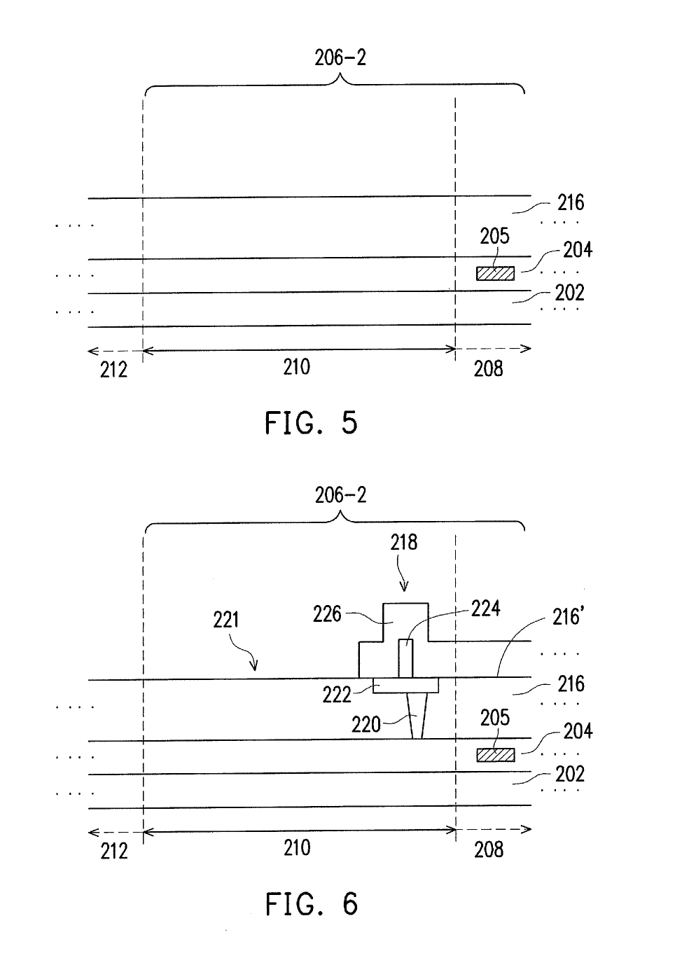

Corresponding to operation 108 of FIG. 1, FIG. 5 illustrates a cross-sectional view of part of the partially formed GaN-based device 206-2 and the left part of the scribe line region 212 that are overlaid by a dielectric layer 216 at one of the various stages of fabrication, according to some embodiments. In some embodiments, the dielectric layer 216 may be formed to overlay the whole GaN-related layer 204. In some embodiments, the dielectric layer 216 may be formed to overlay part of the GaN-related layer 204, for example, the circuit region 208 of the partially formed GaN-based device 206-2, the seal ring region 210 of the partially formed GaN-based device 206-2, and the scribe line region 212 that is around the partially formed GaN-based device 206-2. The dielectric layers 216 may be formed of a low-k dielectric material with a dielectric constant (k value) between about 2.9 and 3.8, an ultra-low-k (ULK) dielectric material with a k value between about 2.5 and about 2.9, or some combination of low-k dielectric materials. For example, the dielectric layer 216 may be formed of fluorinated silica glass (FSG), phosphosilicate glass (PSG), borophosphosilicate glass (BPSG), carbon doped silicon oxide (SiOₓC_{y}), Black Diamond® (Applied Materials of Santa Clara, Calif.), Xerogel, Aerogel, amorphous fluorinated-carbon, Parylene, BCB (bis-benzocyclobutenes), SiLK (Dow Chemical, Midland, Mich.), polyimide, and/or other future developed low-k/ULK dielectric materials.

Corresponding to operation 110 of FIG. 1, FIG. 6 illustrates a cross-sectional view of the partially formed GaN-based device 206-2 including a wall structure 218 that is formed in the seal ring region 210 of the partially formed GaN-based device 206-2 at one of the various stages of fabrication, according to some embodiments. In some embodiments, the wall structure 218 may be formed in the seal ring region 210 that is substantially adjacent to the circuit region 208. As such, in some embodiments, when viewing above, the wall structure 218 may be formed as a ring structure surrounding the circuit region 208.

Further, as shown in FIG. 6, the wall structure 218 includes at least a via structure 220 formed in the dielectric layer 216 that is coupled to the GaN-related layer 204, at least a metallization layer 222 formed in the dielectric layer 216 and coupled to the via structure 220, a conductive plug structure 224 formed above the dielectric layer 216 and coupled to the metallization layer 222, and a passivation layer 226 covering the conductive plug structure 224 and part of a top surface 216′ the dielectric layer 216. In some embodiments, at least part of the wall structure 218, e.g., the via structure 220, the metallization layer 222, and/or the conductive plug structure 224, are formed respectively to collectively surround the circuit region 208. In some embodiments, the passivation layer 226 may be formed to extend over the top surface 216′ of the dielectric layer 216 in both the circuit region 208 and the seal ring region 210, but leave at least an opening 221 to expose a portion of the top surface 216′ of the dielectric layer 216, which may be subsequently used to form a TGV structure that further surrounds the wall structure 218.

Such a TGV structure will be discussed in further detail below with respect to FIG. 8.

In some embodiments, the via structure 220 and the metallization layer 222 may be formed by various depositing, patterning and etching processes. For example, a first patterning process, followed by a respective etching process, are performed to recess the dielectric layer 216 to form a vertical trench; a second patterning process, followed by a respective etching process, are performed to recess further the dielectric layer 216 to form a horizontal trench coupled to the vertical trench; and at least a depositing process is performed to refill the vertical and horizontal trenches so as to form the via structure 220 and the metallization layer 222. It is understood that although only one via structure (e.g., 220) and one metallization layer (e.g., 222) are shown in the illustrated embodiment of FIG. 6, any desired number of via structures and metallization layers can be formed in the dielectric layer 216 while remaining within the scope of the present disclosure. In some embodiments, the via structure 220 and the metallization layer 222 may include a conductive material such as aluminum, aluminum alloy, copper, copper alloy, or combinations thereof.

As mentioned above, in some embodiments, the conductive plug structure 224 may be formed to couple to at least one of the metallization layers (e.g., 222) and its respectively coupled via structure (e.g., 220). The conductive plug structure 224 may be formed of the conductive material that is substantially similar to that of the via structure 220 and the metallization layer 222, e.g., aluminum, aluminum alloy, copper, copper alloy, or combinations thereof. As such, an electrical conduction path may be provided by the via structure 220, the metallization layer 222, and the conductive plug structure 224. In some embodiments, the passivation layer 226 may include one or more dielectric layers such as, for example, a silicon nitride (SiN) layer and/or a silicon oxynitride (SiON) layer. The passivation layer 226 may be deposited by various deposition techniques such as, for example, a chemical vapor deposition (CVD) technique, a physical vapor deposition (PVD) technique, or the like.

Corresponding to operation 112 of FIG. 1, FIG. 7 illustrates a cross-sectional view of the partially formed GaN-based device 206-2 including a vertical trench 230 in the seal ring region 210 that vertically extends through part of the silicon wafer 202, the GaN-related layer 204, and the dielectric layer 216 at one of the various stages of fabrication, according to some embodiments. In some embodiments, the vertical trench 230 is formed at a location around the opening 221. As such, when viewing from the top, the vertical trench 230 may be formed as a ring structure surrounding the wall structure 218.

In some embodiments, the vertical trench 230 is formed by at least some of the following processes: forming a patterned layer 232 (e.g., a photoresist layer) with an opening 232′ that is about the location of the opening 221 over the dielectric layer 216 and the wall structure 218; performing at least one dry/wet etching process to etch through part of the dielectric layer 216 by using the patterned layer 232 as a mask; and continuing using the patterned layer 232 as the mask to perform at least another dry/wet etching process to etch through part of the GaN-related layer 204 and part of the silicon wafer 202. More specifically, in some embodiments, a fluorine-based etchant gas, for example, Tetrafluorocyclopropene (C₃F₄), may be used to etch the dielectric layer 216; and a mixture of fluorine-based and chlorine-based etchant gas, for example, chloride (Cl₂)+C₃F₄, may be used to etch the GaN-related layer 204 and the silicon wafer 202. In some embodiments, after the vertical trench 230 is formed, the patterned layer 232 is removed by one or more stripping processes.

Corresponding to operation 114 of FIG. 1, FIG. 8 illustrates a cross-sectional view of the partially formed GaN-based device 206-2 including a TGV structure 240 in the seal ring region 210 that vertically extends through part of the silicon wafer 202, the GaN-related layer 204, and the dielectric layer 216 at one of the various stages of fabrication, according to some embodiments. In some embodiments, the TGV structure 240 is formed in the vertical trench 230 (FIG. 7). Thus, when viewing from the top, the TGV structure 240 may be formed as a ring structure that surrounds the wall structure 218.

In some embodiments, the TGV structure 240 together with the wall structure 218 is herein referred to as seal ring structure 250. By forming such a seal ring structure 250 in the seal ring region 210 to surround the respective circuit region 208, various mechanical damages (e.g., edge cracks and/or interfacial delamination) that are typically induced by die preparation processes (which will be discussed with respect to FIGS. 9A and 9B) and propagated from the scribe line region 212, through the GaN-related layer 204 in the seal ring region 210, and to the active device component 205 in the circuit region 208, can be advantageously “blocked.” As such, the active device component 205 in the circuit region 208 can be protected from such mechanical damage.

In some embodiments, the TGV structure 240 is formed by depositing a polyimide material and/or a molding compound material 240′ over the circuit region 208, the seal ring region 210, and the scribe line region 212 so as to refill the vertical trench 230 with the material 240′. In some embodiments, the material 240′ may be formed by using a spin-on coating technique or the like. In the example where the material 240′ includes polyimide material, a post-baking process (under temperature of about 300° C. to about 400° C.) may be performed to evaporate excessive solvents that are used to dissolve the polyimide material.

Corresponding to operation 116 of FIG. 1, FIG. 9A illustrates a top view of the GaN-related layer 204 after respective seal ring structures are formed (e.g., 250 of FIG. 8) in respective seal ring regions (e.g., 210) of the plural partially formed GaN-based devices (e.g., 206-1, 206-2, 206-3, 206-4, 206-5, 206-6, 206-7, 206-8, etc.) at one of the various stages of fabrication, according to some embodiments. FIG. 9B is a cross-sectional view, taken along line a-a of FIG. 9A, illustrating part of the partially formed GaN-based device 206-2.

In some embodiments, the aforementioned operations (i.e., operations 110 to 114) to form the seal ring structure 250 for the partially formed GaN-based device 206-2 can be used to form a respective seal ring structure for each of other partially formed GaN-based devices (e.g., 206-1, 206-3, 206-4, 206-5, 206-6, 206-7, 206-8, etc.) across the silicon wafer 202 and the GaN-related layer 204. Accordingly, by performing the operations 110 to 114 on those other partially formed GaN-based devices (e.g., 206-1, 206-3, 206-4, 206-5, 206-6, 206-7, 206-8, etc.) across the silicon wafer 202 and the GaN-related layer 204, concurrently or respectively, with the partially formed GaN-based device 206-2, each partially formed GaN-based device across the silicon wafer 202 may include its respective seal ring structure formed in the seal ring region that surrounds its respective circuit region. In some embodiments, after all or at least part of partially formed GaN-based devices (e.g., 206-1, 206-2, 206-3, 206-4, 206-5, 206-6, 206-7, 206-8, etc.) across the silicon wafer 205 include respective seal ring structures, plural die cutting lines, which are symbolically shown as 251, 253, 255, and 257, in respective scribe line regions may be available for die preparation processes to begin. In other words, the die preparation process may follow each die cutting line to singulate the partially GaN-based devices.

For example, plural die preparation processes may follow the die cutting lines 251, 523, 255, and 257, respectively, so as to singulate the partially formed GaN-based device 206-2 from other partially formed GaN-based devices. In some embodiments, after being singulated, the partially formed GaN-based device 206-2 may become the GaN-based device 200, which is shown in FIG. 9B. In the illustrated embodiment of FIG. 9B, it is noted that after the die preparation processes, the scribe line region 212 may either vanish or become substantially small. Also, it is noted that after the die preparation processes, the scribe line region 212, if any, may become an outermost ring structure that surrounds the respective seal ring region 210 and circuit region 208.

In an embodiment, a semiconductor device includes a substrate, overlaid by a III-V compound semiconductor layer. The substrate includes a circuit region and a seal ring region, wherein the seal ring region surrounds the circuit region. A seal ring structure is disposed in the seal ring region, wherein the seal ring structure includes a first via structure, extending through part of the substrate and the III-V compound semiconductor layer, that surrounds the circuit region.

In another embodiment, a semiconductor device includes a substrate, overlaid by a III-V compound semiconductor layer and further by a dielectric layer. The substrate includes a circuit region and a seal ring region. The seal ring region surrounding the circuit region. A seal ring structure disposed in the seal ring region, wherein the seal ring structure includes a first via structure, extending through part of the substrate, the III-V compound semiconductor layer, and the dielectric layer, that surrounds the circuit region.

Yet in another embodiment, a method including providing a wafer overlaid by at least one III-V compound semiconductor layers and a dielectric layer; forming plural III-V compound semiconductor-based active circuit components in respective circuit regions across the wafer; and forming a respective seal ring structure to surround each of the circuit regions, wherein each seal ring structures includes a wall structure surrounds the respective circuit region and a first via structure further surrounds the respective wall structure.

The foregoing outlines features of several embodiments so that those ordinary skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a substrate, overlaid by a III-V compound semiconductor layer, including a circuit region and a seal ring region, the seal ring region surrounding the circuit region; and
a seal ring structure disposed in the seal ring region,
wherein the seal ring structure includes a first via structure, extending through part of the substrate and the III-V compound semiconductor layer, that surrounds the circuit region.

2. The device of claim 1, wherein the first via structure further extends through a dielectric layer overlaying the III-V compound semiconductor layer.

3. The device of claim 2, wherein the seal ring structure further comprises a wall structure that surrounds the circuit region and is surrounded by the first via structure.

4. The device of claim 3, wherein the wall structure includes at least a second via structure and a metallization layer coupled to the second via structure that are disposed within the dielectric layer, a conductive plug structure coupled to the metallization layer that is disposed above the dielectric layer, and a passivation layer that overlays the conductive plug structure, the metallization layer, and the second via structure.

5. The device of claim 1, wherein the III-V compound semiconductor layer includes at least a gallium nitride (GaN) layer.

6. The device of claim 1, wherein the first via structure includes either a polyimide material or a molding compound material.

7. The device of claim 1, further comprising one or more active circuit components disposed in the circuit region that are each part of a gallium nitride (GaN)-based device.

8. The device of claim 7, wherein the one or more active circuit components are formed in the III-V compound semiconductor layer.

9. A semiconductor device, comprising:
a substrate, overlaid by a III-V compound semiconductor layer and further by a dielectric layer including a circuit region and a seal ring region, the seal ring region surrounding the circuit region; and
a seal ring structure disposed in the seal ring region,
wherein the seal ring structure includes a first via structure, extending through part of the substrate, the III-V compound semiconductor layer, and the dielectric layer, that surrounds the circuit region.

10. The device of claim 9, wherein the seal ring structure further comprises a wall structure that surrounds the circuit region and is surrounded by the first via structure.

11. The device of claim 10, wherein the wall structure includes at least a second via structure and a metallization layer coupled to the second via structure that are disposed within the dielectric layer, a conductive plug structure coupled to the metallization layer that is disposed above the dielectric layer, and a passivation layer that overlays the conductive plug structure, the metallization layer, and the second via structure.

12. The device of claim 9, wherein the III-V compound semiconductor layer includes at least a gallium nitride (GaN) layer.

13. The device of claim 9, wherein the first via structure includes either a polyimide material or a molding compound material.

14. The device of claim 9, further comprising one or more active circuit components disposed in the circuit region that are each part of a gallium nitride (GaN)-based device.

15. The device of claim 14, wherein the one or more active circuit components are formed in the III-V compound semiconductor layer.

16. The device of claim 9, wherein the III-V compound semiconductor layer includes plural sub layers that is each formed of at least one of the following elements: indium (In), gallium (Ga), phosphide (P), arsenide (As), and nitride (N).

17. A method, comprising:
providing a wafer overlaid by at least one III-V compound semiconductor layer and a dielectric layer;
forming plural III-V compound semiconductor-based active circuit components in respective circuit regions across the wafer; and
forming a respective seal ring structure to surround each of the circuit regions, wherein each seal ring structures includes a wall structure surrounds the respective circuit region and a first via structure further surrounds the respective wall structure, wherein the first via structure extends through part of the wafer, the at least one III-V compound semiconductor layer, and the dielectric layer.

18. The method of claim 17, wherein the III-V compound semiconductor layer includes at least a gallium nitride (GaN) layer.

19. (canceled)

20. The method of claim 17, wherein the wall structure includes at least a second via structure and a metallization layer coupled to the second via structure that are disposed within the dielectric layer, a conductive plug structure coupled to the metallization layer that is disposed above the dielectric layer, and a passivation layer that overlays the conductive plug structure, the metallization layer, and the second via structure.

21. The method of claim 17, wherein the first via structure includes at least one of a polyimide material and a molding compound material.
